(19) United States
(12) Patent Application Publication
(10) Pub. No.: US 2026/0129951 A1
(43) Pub. Date: May 7, 2026

(54) SEMICONDUCTOR CHIP AND METHOD OF MANUFACTURING THE SAME

(71) Applicant: SAMSUNG ELECTRONICS CO., LTD., Suwon-si (KR)

(72) Inventors: Seongmin Son, Suwon-si (KR); Joohee Jang, Suwon-si (KR); Junhong Min, Suwon-si (KR); Seungdon Lee, Suwon-si (KR); Hyunjin Lee, Suwon-si (KR); Hojin Lee, Suwon-si (KR)

(21) Appl. No.: 19/224,656

(22) Filed: May 30, 2025

(30) Foreign Application Priority Data
Nov. 5, 2024 (KR) 10-2024-0155058

(51) Int. Cl. H01L 23/00; H01L 25/18; H10B 80/00; H10D 80/30

(52) U.S. Cl. CPC H10D 80/30; H10B 80/00; H10W 90/00; H10W 72/981; H10W 72/983; H10W 90/722; H10W 90/792

(57) ABSTRACT

An example semiconductor device includes a first semiconductor structure including a first semiconductor substrate and a first interconnection layer disposed on the first semiconductor substrate and including first interconnection structures and first bonding pads connected to the first interconnection structures and exposed on an upper surface; a second semiconductor structure including a second semiconductor substrate disposed on the first semiconductor structure, and a second interconnection layer disposed on the second semiconductor substrate, and including second interconnection structures, and second bonding pads connected to the second interconnection structures and exposed on a lower surface; and a buffer structure extending from at least one of side surfaces of the first semiconductor structure and the second semiconductor structure to a bonding surface between the first interconnection layer and the second interconnection layer.

### CROSS-REFERENCE TO RELATED APPLICATION

This application claims benefit of priority to Korean Patent Application No. 10-2024-0155058 filed on Nov. 5, 2024, in the Korean Intellectual Property Office, the disclosure of which is incorporated herein by reference in its entirety.

### BACKGROUND

As electronic devices have been designed to be lightweight and to have high-performance, a semiconductor chip having a reduced weight and high-performance is desired. High performance may be implemented by a stack structure of semiconductor chips, but a process of dicing and attaching a plurality of semiconductor chips formed on a semiconductor wafer may be performed individually, such that process yield may be lowered.

### SUMMARY

The present disclosure relates to a bonded semiconductor device having improved reliability.

In general, according to some aspects, a semiconductor device includes a first semiconductor structure including a first semiconductor substrate and a first interconnection layer disposed on the first semiconductor substrate and including first interconnection structures and first bonding pads connected to the first interconnection structures and exposed on an upper surface; a second semiconductor structure including a second semiconductor substrate disposed on the first semiconductor structure, and a second interconnection layer disposed on the second semiconductor substrate, and including second interconnection structures, and second bonding pads connected to the second interconnection structures and exposed on a lower surface; and a buffer structure extending from at least one of side surfaces of the first semiconductor structure and the second semiconductor structure to a bonding surface between the first interconnection layer and the second interconnection layer.

In general, according to some aspects, a semiconductor device includes a first semiconductor structure including a first semiconductor substrate and a first interconnection layer disposed on the first semiconductor substrate and including a first interconnection structure; a second semiconductor structure including a second semiconductor substrate disposed on the first semiconductor structure, and a second interconnection layer disposed on a lower portion of the second semiconductor substrate and including a second interconnection structure; bonding structures in which first bonding pads connected to the first interconnection structure and having upper surfaces exposed from the first interconnection layer and second bonding pads connected to the second interconnection structure and having lower surfaces exposed from the second interconnection layer are bonded to each other vertically; and a buffer structure filling a side recess portion recessed from an outer side toward an outermost bonding structure among the bonding structures between an upper surface of the first interconnection layer and a lower surface of the second interconnection layer.

In general, according to some aspects, a semiconductor device includes a base structure including lower connection pads disposed on a lower surface and upper connection pads disposed on an upper surface and electrically connected to the lower connection pads; at least one bonding chip structure disposed on the base structure, including two semiconductor chip structures bonded to each other, and including connection pads on a lower surface; and solder bumps attaching the upper connection pads to the connection pads, wherein the at least one bonding chip structure includes a first semiconductor structure including a first semiconductor substrate and a first interconnection layer disposed on the first semiconductor substrate and including first interconnection structures and first bonding pads connected to the first interconnection structures and exposed on an upper surface, on the base structure; a second semiconductor structure including a second semiconductor substrate disposed on the first semiconductor structure, and a second interconnection layer disposed on a lower portion of the second semiconductor substrate and including second interconnection structures and second bonding pads connected to the second interconnection structures and exposed on a lower surface; and a buffer structure extending from at least one side surface of the first semiconductor structure and the second semiconductor structure to a bonding surface between the first interconnection layer and the second interconnection layer.

In general, according to some aspects, a method of manufacturing a semiconductor device includes disposing a first semiconductor wafer having a first thickness and including a first semiconductor substrate and a first interconnection layer on a carrier substrate; forming a bonded structure by attaching a second semiconductor wafer having a second thickness on the first semiconductor wafer; injecting a first filler into a first recess portion formed on an edge of a bonding surface between the first semiconductor wafer and the second semiconductor wafer of the bonded structure; injecting a second filler into a second recess portion on the first recess portion on side surfaces of the first semiconductor wafer and the second semiconductor wafer of the bonded structure; forming a buffer structure including the first recess portion and the second recess portion buried therein by curing the first filler and the second filler; forming a thickness to be smaller than the second thickness by thinning a back surface of the second semiconductor wafer; forming a thickness to be smaller than the first thickness by thinning a back surface of the first semiconductor wafer; and cutting the bonded structure into unit chip structures.

The injecting the first filler may include injecting a liquid insulating material having a first viscosity into the first recess portion.

The injecting the second filler may include injecting a liquid insulating material having a second viscosity higher than the first viscosity into the second recess portion.

The curing the first filler and the second filler may include curing to have a first density by vaporizing impurities in the first filler.

The first and second semiconductor wafers may include a side surface having a curved surface protruding outwardly, include the second recess portion between the side surfaces, and a non-adhesive region among a front surface of the first semiconductor wafer and a front surface of the second semiconductor wafer forms the first recess portion.

### BRIEF DESCRIPTION OF THE DRAWINGS

The above and other aspects, features, and advantages of the present disclosure will be more clearly understood from the following detailed description, taken in combination with the accompanying drawings.

FIG. 1 is a flowchart illustrating an example of a method of manufacturing a semiconductor device.

FIGS. 2A, 2B, 3, 4A, 4B, 5A, 5B, 6, 7, 8, and 9 are a perspective diagram, a cross-sectional diagram, and a diagram viewed from above, illustrating processes of the example manufacturing method in FIG. 1.

FIGS. 10A, 10B, 10C, and 10D are diagrams viewed from above illustrating an example of a semiconductor device.

FIGS. 10E, 11, 12, 13, and 14 are cross-sectional diagram illustrating an example of a semiconductor device.

FIG. 15 is a cross-sectional diagram illustrating an example of a semiconductor package.

### DETAILED DESCRIPTION

Hereinafter, implementations of the present disclosure will be described as follows with reference to the accompanying drawings.

In some implementations, a first semiconductor wafer 100 including first chip regions 102 disposed therein and a second semiconductor wafer 200 including second chip regions 202 disposed therein may be formed, and a bonded wafer structure may be formed by bonding the first semiconductor wafer 100 to the second semiconductor wafer 200. In some implementations, by structurally reinforcing the bonded wafer structure, performing thinning, and cutting the structure into bonded unit chip structures, semiconductor devices in which the first chip structure and the second chip structure are bonded to each other may be formed.

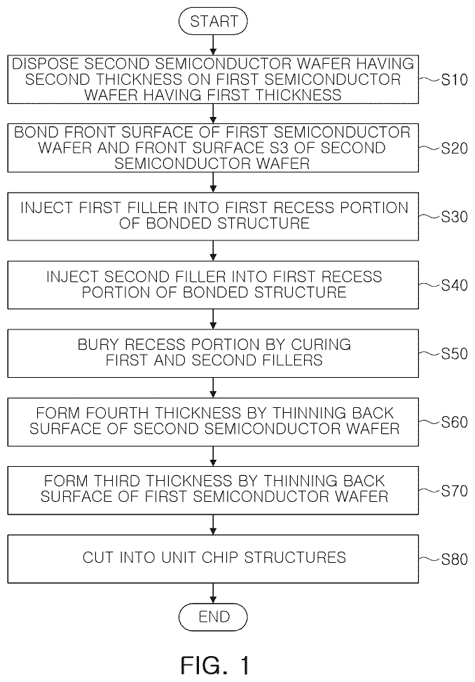

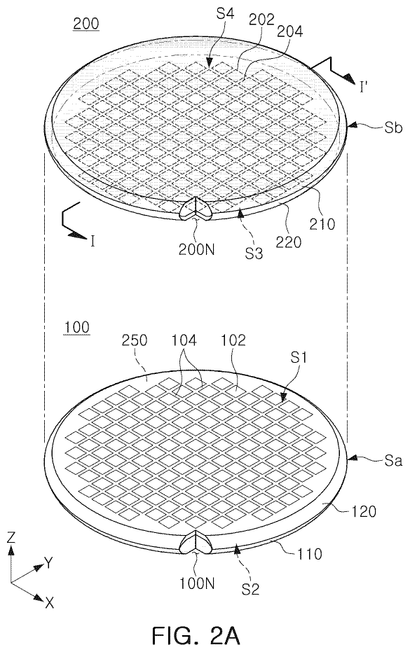

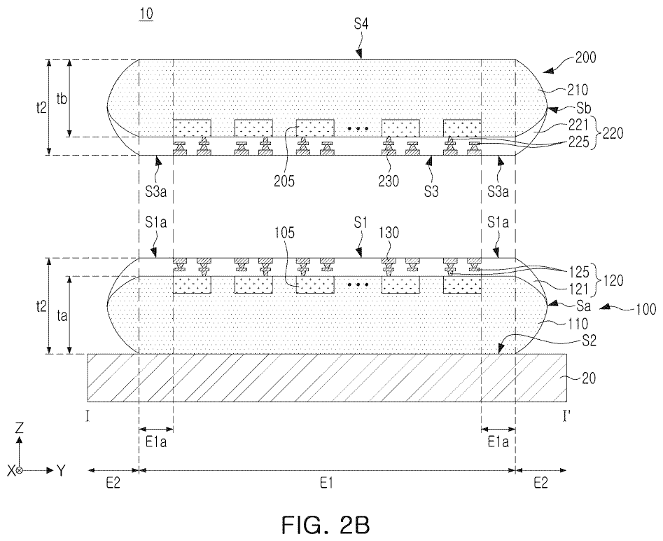

FIG. 1 is a flowchart illustrating an example of a method of manufacturing a semiconductor device. FIGS. 2A, 2B, 3, 4A, 4B, 5A, 5B, 6, 7, 8, and 9 are a perspective diagram, a cross-sectional diagram, and a diagram viewed from above, illustrating processes of the example manufacturing method in FIG. 1. FIG. 2A is a perspective diagram illustrating two semiconductor wafers, and FIGS. 2B to 9 each illustrate a cross-sectional diagram illustrating the two semiconductor wafers taken along line I-I′.

Referring to FIG. 1, FIGS. 2A and 2B, first chip regions 102 may be formed on a first semiconductor wafer 100, second chip regions 202 may be formed on a second semiconductor wafer 200, and the second semiconductor wafer 200 may be disposed on the first semiconductor wafer 100 (S10).

As illustrated in FIGS. 2A and 2B, a first semiconductor wafer 100 including a front surface S1 and a back surface S2 may be disposed on a base substrate 20, and first chip regions 102 may be formed on the front surface S1.

The first semiconductor wafer 100 may include the front surface S1 and the back surface S2 opposite to the front surface S1, and may include a first side surface Sa between the front surface S1 and the back surface S2. The first side surface Sa of the first semiconductor wafer 100 may have an outwardly curved surface so as to protrude from an edge of the front surface S1 and an edge of the back surface S2 to an external side. The first side surface Sa of the first semiconductor wafer 100 may have an overall curved surface, and may include a curved surface having an inflection point at a center of the first side surface Sa so as to have the largest diameter at the center of the first side surface Sa, but an example implementation thereof is not limited thereto.

The first chip regions 102 may be arranged in a matrix form on the front surface S1 of the first semiconductor wafer 100, and spacing regions 104 may be disposed between the first chip regions 102. The spacing regions 104 may be defined as a scribe lane as a space which may isolate the first chip regions 102. The first chip regions 102 occupy most of the area on the front surface S1 of the first semiconductor wafer 100, and may be disposed in a region other than the edge regions E1a.

Accordingly, the first semiconductor wafer 100 may include a first region E1 corresponding to the front surface S1 and a second region E2 corresponding to the first side surface Sa. The first region E1 may include an active region in which the first chip regions 102 are disposed and an edge region E1a surrounding the region and connected to the second region E2. The second region E2 may be defined as a region protruding from the front surface S1 by the curved surface of the first side surface Sa of the first semiconductor wafer 100.

In the cross section in FIG. 2B, the second region E2 may be disposed on both sides of the first region E1 as illustrated, or the second region E2 may be disposed by surrounding the first region E1.

The edge region E1a may be a dummy region adjacent to the second region E2, and may be disposed between the second region E2 and the first chip regions 102, and in particular, the edge region E1a may be disposed between the second region E2 and the first chip regions 102 disposed in an outermost region.

The edge region E1a may be defined as a region to the outermost first chip regions 102 from the edges of the front surface S1 and the back surface S2. That is, the space between the first chip regions 102 may be defined as a spacing region 104, which is a scribe lane, and the space between the outermost first chip regions 102 and the second region E2 may be defined as an edge region E1a.

In the cross-section in FIG. 2B, the edge region E1a may be disposed on both sides of the outermost first chip regions 102 as illustrated, or the outermost first chip regions 102 may surround surfaces not facing other first chip regions 102 between the outermost first chip regions 102 and the second regions E2. Depending on the arrangement of the outermost first chip regions 102, the distances in the radial direction (toward the center of the first semiconductor wafer) of the edge region E1a may be different. The edge region E1a may be a region cut by cutting the first chip regions 102, and as a region in which the first bonding pads 130 are not disposed.

The first semiconductor wafer 100 may include a first semiconductor substrate 110 and a first interconnection layer 120 on the first semiconductor substrate 110. The semiconductor wafer 100 may have a notch 100N in one region of a corner, which is used as a reference point for wafer alignment.

The first semiconductor substrate 110 may include silicon. The semiconductor substrate 110 may include an upper surface adjacent to the front surface S1 of the first semiconductor wafer 100, a back surface S2 adjacent to the back surface S2 of the first semiconductor wafer 100, and a side surface between the upper surface and the back surface S2. The side surface of the first semiconductor substrate 110 may be a lower region of the first side surface Sa of the first semiconductor wafer 100.

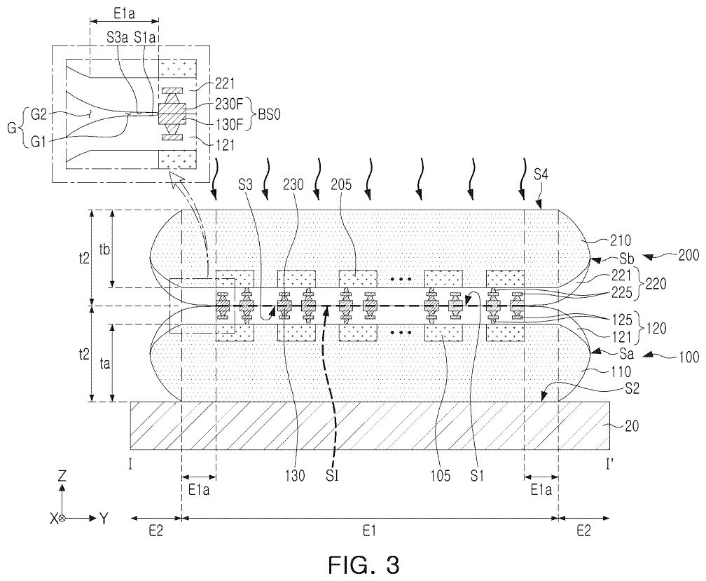

On the first semiconductor substrate 110, first active regions 105 including various impurity regions for individual devices and device isolation structures such as shallow trench isolation (STI) structures in the first chip regions 102, and including metal materials forming a portion of interconnection structures may be formed. According to FIG. 3, the first active regions 105 may be disposed in the first semiconductor substrate 110, or devices on the upper surface and STI in the first semiconductor substrate 110 may be included.

The first active regions 105 of the first semiconductor substrate 110 may further form assigned devices, for example, memory devices, logic circuit devices, and transistors and passive devices may be formed.

The first interconnection layer 120 may be formed on an upper surface of the first semiconductor substrate 110. The first interconnection layer 120 may include an interconnection structure 125 connected to a plurality of individual devices formed on the upper surface of the semiconductor substrate 110. As illustrated in FIG. 2B, the interconnection structure 125 may include a metal interconnection layer and a metal via. For example, the multilayer interconnection structure 125 may be a multilayer structure including two or more metal interconnection layers and/or two or more vias. The interconnection structure 125 may be connected to first bonding pads 130 disposed on the upper surface of the first interconnection layer 120.

The first bonding pads 130 may be exposed on the upper surface of the first interconnection layer 120 and may be connected to the interconnection structure 125. The first bonding pads 130 may include a conductive metal material and may be formed as bonding pads for direct bonding without a connection member (e.g., solder bump, copper post, or the like). The first bonding pads 130 may include, for example, copper, silver, gold, or the like, but an example implementation thereof is not limited thereto.

The multilayer interconnection structure 125 and the first bonding pads 130 may be formed in the first insulating layer 121, and the first insulating layer 121 may be an oxide or a nitride, and for example, may include at least one of silicon oxide (SiO₂), silicon nitride (SiN), and silicon carbonitride (SiCN).

When the first semiconductor wafer 100 and the second semiconductor wafer 200 are bonded to each other, direct bonding between the first bonding pads 130 and the second bonding pads 230 may be performed, or alternatively, hybrid bonding in which dielectric-dielectric bonding and metal-metal bonding are performed together may be performed. When hybrid bonding is performed, the upper surface of the first insulating layer 121 and the upper surface of the first bonding pads 130 may be substantially coplanar with each other, or the upper surface of the first bonding pads 130 may have a slightly protruding shape, but an example implementation thereof is not limited thereto. In the case of hybrid bonding, the first insulating layer 102 may include a multilayer insulating layer, and the insulating layer on the uppermost end may function as a bonding insulating layer.

The upper surface of the first interconnection layer 120 may be defined as the front surface S1 of the first semiconductor wafer 100, and the side surface of the first interconnection layer 120 may form an upper region of the first side surface Sa of the first semiconductor wafer 100, and may be continuously connected to the side surface of the first semiconductor substrate 110 while the thickness of the first insulating layer 121 of the first interconnection layer 120 decreases downwardly in the Z-direction.

The first semiconductor wafer 100 may have a first thickness t1 in the Z-direction, and the first semiconductor substrate 110 may occupy most of the first thickness t1 and may have a first substrate thickness ta less than the first thickness t1.

When the formation of the first bonding pads 130 of the first interconnection layer 120 on the first semiconductor substrate 110 is completed, the second semiconductor wafer 200 may be formed.

The second semiconductor wafer 200 may be formed on a base substrate different from the first semiconductor wafer 100. The second semiconductor wafer 200 may form the second interconnection layer 220 on the second semiconductor substrate 210 and the second semiconductor substrate 210, similarly to the first semiconductor wafer 100. The second semiconductor wafer 200 may have a notch 200N used as a reference point for wafer alignment in a region of a corner, and devices may be formed to be aligned with each other based on the notches 100N and 200N of the first and second semiconductor wafers 100 and 200.

A second semiconductor wafer 200 may be disposed on the base substrate, and second chip regions 202 may be formed on the front surface S3.

The second semiconductor wafer 200 may include a front surface S3 and a back surface S4 opposite to the front surface S3, and may include a second side surface Sb between the front surface S3 and the back surface S4. The front surface S3 of the second semiconductor wafer 200 may have an area and a shape the same as or similar to those of the front surface S1 of the first semiconductor wafer 100. The second side surface Sb of the second semiconductor wafer 200 may include a curved surface protruding to the external side, and may have an outwardly curved surface protruding to an outer side from an edge of the front surface S3 and an edge of the back surface S4. The second side surface Sb may have substantially the same curvature as that of the first side surface Sa of the first semiconductor wafer 100, but an example implementation thereof is not limited thereto.

Second chip regions 202 may be arranged in a matrix form on the front surface S3 of the second semiconductor wafer 200, and spacing regions 204 may be disposed between the second chip regions 202. The second chip regions 202 may be formed to correspond to the first chip regions 102 of the first semiconductor wafer 100. The second chip regions 202 may occupy most of the area on the front surface S3 of the second semiconductor wafer 200, and may be disposed in a region other than the edge regions E1a.

Accordingly, the second semiconductor wafer 200 may include the front surface S3, and may include a first region E1 in which the second chip regions 202 are disposed and a second region E2 surrounding the first region E1 and protruding by the second side surface Sb. The edge region E1a of the first region E1 may be a dummy region and may correspond between the second chip regions 202 and the second region E2.

The first region E1 of the second semiconductor wafer 200 and the first region E1 of the first semiconductor wafer 100 may be substantially the same and aligned in the Z-direction, and the second regions E2 of the second semiconductor wafer 200 and the first semiconductor wafer 100 may be substantially the same and aligned in the Z-direction.

The edge region E1a may include the front surface S3 and the back surface S4 of the second semiconductor wafer 200, and may be defined as a region from edges of the front surface S3 and the back surface S4 to the outermost second chip regions 202. The edge region E1a may be considered as a region mainly cut off by cutting of the second chip regions 202, and may be considered as a region in which the second bonding pad 230 is not disposed.

The second semiconductor substrate 210 may include silicon. The second semiconductor substrate 210 may include an upper surface close to the front surface S3 of the second semiconductor wafer 200, a back surface close to the back surface S4 of the second semiconductor wafer 200, and a side surface between the upper surface and the back surface. The side surface of the second semiconductor substrate 210 may be a lower region of the second side surface Sb of the second semiconductor wafer 200.

On the second semiconductor substrate 210, a second active regions 205 including various impurity regions for individual devices and device isolation structures such as shallow trench isolation (STI) structures in each of the second chip regions 202, and including a metal material forming a portion of an interconnection structure may be formed. In FIG. 3, the second active regions 205 may be formed in the first semiconductor substrate 210, but the second active regions 205 may include device layers formed on the first semiconductor substrate 210. The second active regions 205 of the second semiconductor substrate 210 may further form allocated devices, for example, logic circuit devices may be included, and transistors and passive devices may be formed.

The first and second active regions 105 and 205 of the first semiconductor substrate 110 and the second semiconductor substrate 210 may include the same devices disposed therein, but an example implementation thereof is not limited thereto. That is, the same memory devices may be formed in the first semiconductor substrate 110 and the second semiconductor substrate 210, or alternatively, memory devices may be disposed in the first semiconductor substrate 110, and peripheral circuit devices for driving the memory devices of the first semiconductor substrate 110 may be formed in the second semiconductor substrate 210.

A second interconnection layer 220 may be formed on the upper surface of the second semiconductor substrate 210. The second interconnection layer 220 may form an interconnection structure 225 connected to a plurality of individual devices formed on the upper surface of the second semiconductor substrate 210. As illustrated in FIG. 2B, the interconnection structure 225 may be connected to second bonding pads 230 disposed on the upper surface of the second interconnection layer 220.

The second bonding pads 230 may be exposed on the upper surface of the second interconnection layer 220 and may be connected to the interconnection structure 125. The second bonding pads 230 may include a conductive material and may form bonding pads for direct bonding without a connection member (e.g., solder bump, copper post, or the like). The second bonding pads 230 may include a conductive metal material, for example, copper, silver, gold, or the like, but an example implementation thereof is not limited thereto.

The multilayer interconnection structure 225 and the second bonding pads 230 may be formed in the second insulating layer 221, and the second insulating layer 221 may be an oxide or a nitride, for example, at least one of silicon oxide (SiO₂), silicon nitride (SiN), and silicon carbonitride (SiCN).

When the first semiconductor wafer 100 and the second semiconductor wafer 200 are bonded to each other, direct bonding between the first bonding pads 130 and the second bonding pads 230 may be performed, or alternatively, hybrid bonding in which dielectric-dielectric bonding and metal-metal bonding are performed together may be performed. When hybrid bonding is performed, the upper surface of the second insulating layer 221 and the upper surface of the second bonding pads 230 may be coplanar with each other.

The upper surface of the second interconnection layer 220 may be defined as the front surface S3 of the second semiconductor wafer 200, and the side surface of the second interconnection layer 220 may form the upper region of the second side surface Sb of the second semiconductor wafer 200, and may be continuously connected to the side surface of the second semiconductor substrate 210 while the thickness of the second insulating layer 221 of the second interconnection layer 220 decreases downwardly in the Z-direction.

The second semiconductor wafer 200 may have a second thickness t2 in the Z-direction, and the second semiconductor substrate 210 may occupy most of the second thickness t2 and may have a second substrate thickness tb less than the second thickness t2. The first substrate thickness ta of the first semiconductor substrate 110 and the second substrate thickness tb of the second semiconductor substrate 210 may be substantially the same, but an example implementation thereof is not limited thereto.

As illustrated in FIGS. 2A and 2B, as for the first semiconductor wafer 100 and the second semiconductor wafer 200 formed on each of the base substrates 20, the second semiconductor wafer 200 may be disposed upside down such that the front surface S1 of the first semiconductor wafer 100 and the front surfaces S1 and S3 of the second semiconductor wafer 200 may face each other.

The arrangement of the second semiconductor wafer 200 may be disposed such that the second chip regions 202 and the first chip regions 102 may overlap each other in the Z-direction, and the first bonding pads 130 and the second bonding pads 230 may overlap each other in the Z-direction.

Accordingly, the first regions E1 of the first semiconductor wafer 100 and second semiconductor wafer 200 may overlap each other in the Z-direction, the second regions E2 may overlap each other in the Z-direction, and the edge regions E1a may overlap each other.

Referring to FIG. 1 and FIG. 3, the front surface S1 of the first semiconductor wafer 100 and the front surface S3 of the second semiconductor wafer 200 may be bonded to each other to face each other (S20).

The second chip regions 202 of the second semiconductor wafer 200 and the first chip regions 102 of the first semiconductor wafer 100 may be bonded to overlap each other in the Z-direction, and the first bonding pads 130 and the second bonding pads 230 may be bonded to overlap each other in the Z-direction. This bonding may be performed by performing annealing, plasma, laser, or the like such that the first bonding pads 130 and the second bonding pads 230 may be bonded and bonding structures BS may be formed. This bonding may include performing direct bonding, hybrid bonding, or other various bonding processes.

By the bonding process, the front surfaces S1 and S3 of the first semiconductor wafer 100 and the second semiconductor wafer 200 may be attached to each other and the bonding surface S1 may be formed.

The bonding surface S1 may be defined as the entire front surfaces S1 and S3 of the first semiconductor wafer 100 and the second semiconductor wafer 200, but a partial region, that is, a non-bonding region not in contact in the edge region E1a close to the first side surface Sa and the second side surface Sb among the front surfaces S1 and S3 of the first semiconductor wafer 100 and the second semiconductor wafer 200, may be formed. The non-bonding region may be the entirety of or at least a portion of the edge region E1a.

By the bonding process, a recess portion G may be formed between the side surfaces Sa and Sb of the bonded structure. The recess portion G may include a first recess portion G1 in the edge region E1a and a second recess portion G2 in the second region E2.

The first recess portion G1 may be a region in which the front surface S1 of the first semiconductor wafer 100 of the edge region E1a and the front surface S3 of the second semiconductor wafer 200, specifically, in the non-bonding region, the front surfaces S1 and S3 connected to the first and second side surfaces Sa and Sb may not be in contact with each other and may be partially spaced apart from each other to form a space.

The first recess portion G1 may be formed between the two front surfaces S1 and S3 in the form of a slit having a relatively small height. The length in the radial direction of the first recess portion G1 may be equal to or less than a distance from an edge of the front surfaces S1 and S3 to the outermost bonding structures BSo formed by the outermost first and second bonding pads 130 and 230.

The second recess portion G2 may extend from the first recess portion G1 and may have an inwardly shaped shape formed by curved surfaces of the first and second side surfaces Sa and Sb. The second recess portion G2 may have a width increasing from the first recess portion G1 toward the external side, and may be disposed symmetrically as the two outwardly curved surfaces converge to the first recess portion G1.

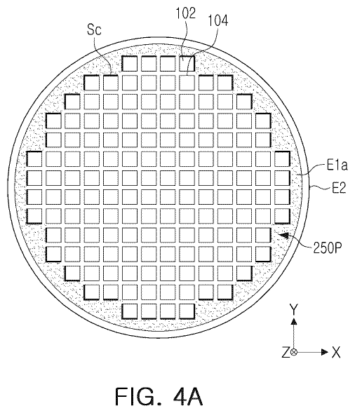

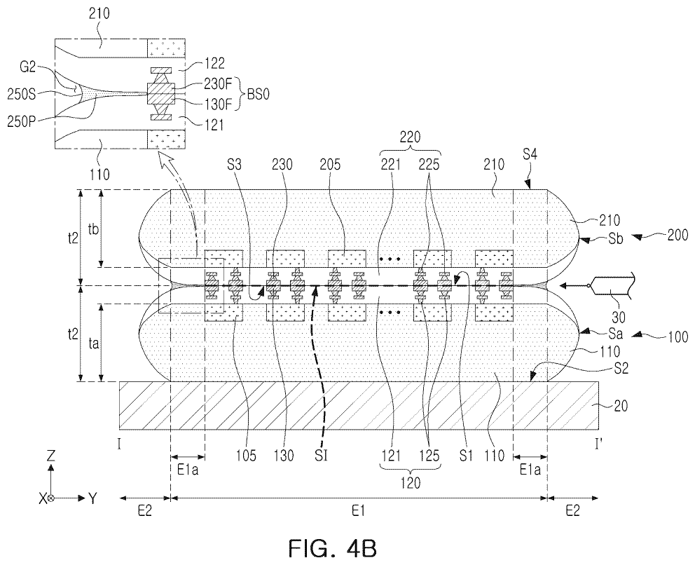

Referring to FIG. 1, FIGS. 4A and 4B, a first filler 250P may be injected into the first recess portion G1 of the bonded structure (S30).

Specifically, the first filler 250P may be injected into the first recess portion G1 of the bonded structure through the injection device 30.

After filling the injection device 30 with the first filler 250P, the first filler 250P may be uniformly injected into the first recess portion G1 of the first and second side surfaces Sa and Sb by discharging the first filler 250P at a constant speed while rotating the base substrate 20.

The first filler 250P may diffuse until the filler is in contact with the outermost bonding structures BSo of the first chip regions 102 and second chip regions 202, which fill the first recess portion G1 of the first and second side surfaces Sa and Sb and are disposed in the outermost portion. Accordingly, as illustrated in FIG. 4A, the region in which the first filler 250P diffuses is limited, and the side surface of the first chip regions 102 and the second chip regions 202 in contact with the first filler 250P may be defined as the reinforcing side surface Sc. As illustrated in FIG. 4A, a portion of the first chip regions 102 and the second chip regions 202, disposed in the outermost portion, may include one reinforcing side surface Sc, another portion may include two reinforcing side surfaces Sc, and the other portion may include up to three reinforcing side surfaces Sc.

The first filler 250P injected into the first recess portion G1 may include an insulating material having an ultra-low viscosity first viscosity, and may be discharged in a liquid form and may diffused into a thin slit of the first recess portion G1 through a capillary phenomenon. The first filler 250P may include high concentrations of oxygen, carbon, or nitrogen impurities in an insulating material such as silicon oxide, silicon nitride, and undoped polysilicon.

When the first filler 250P is injected into the first recess portion G1, the first filler 250P may be cured by heat treatment. When the first filler 250P is cured in the first recess portion G1, the first recess portion G1 may have a curved surface such that the external side surface 250S, which is an exposed surface, may be recessed to an inner side while filling the first recess portion G1.

When the first filler 250P is cured by heat treatment, oxygen, carbon or nitrogen contained inside may be vaporized in the form of H₂O, CO₂, or the like and may be released to an external entity, and the first filler 250P in the first recess portion G1 may have a relatively low first density.

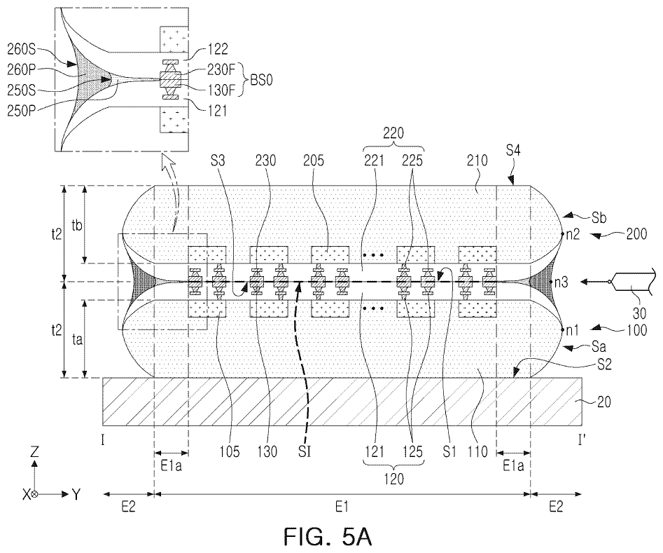

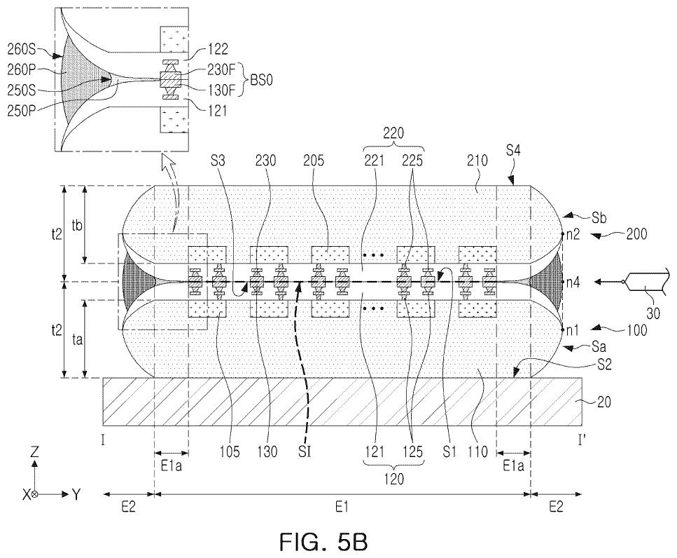

As illustrated in FIGS. 1, 5A and 5B, the second filler may be injected into the second recess portion G2. The second filler 260P may be injected into the second recess portion G2 of the bonded structure through the injection device 30 (S40).

After the second filler 260P is injected into the injection device 30, the second filler 260P may be injected into the second recess portion G2 of the side surface at a constant speed while rotating the base substrate 20.

The second filler 260P injected into the second recess portion G2 may include an insulating material having a low viscosity second viscosity, and may be discharged in a liquid form and may be filled to bury the second recess portion G2. The second viscosity may have a value greater than the first viscosity, and may be provided in a liquid state, but may not flow and may be retained in the second recess portion G2. The second filler 260P may be polysilicon, silicon oxide, silicon nitride, or the like, but an example implementation thereof is not limited thereto.

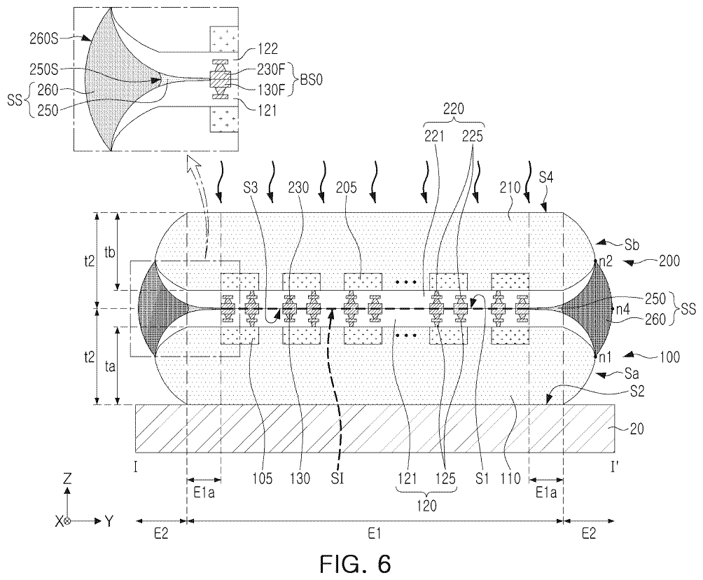

When the second filler 260P is injected into the second recess portion G2, the second filler 260P may be cured by heat treatment as in FIG. 6 (S50). When the second filler 260P is cured in the second recess portion G2, the exposed surface 260S may have a curved surface so as to be recessed toward an inner side as in FIG. 5A while filling the second recess portion G2.

Accordingly, the exposed surfaces 250S and 260S of the first filler 250P and the second filler 260P may be formed to have curvatures in the same direction. In this case, the center point n3 of the exposed surface 260S of the second filler 260P may be recessed toward the inner region than the outermost points n1 and n2 of the first and second side surfaces Sa and Sb, but an example implementation thereof is not limited thereto.

As illustrated in FIG. 5B, the exposed surface 260S of the second filler 260P may have a curved surface so as to be outwardly curved toward the external side. Accordingly, the exposed surfaces 250S and 260S of the first filler 250P and the second filler 260P may have curved surfaces in different directions. In this case, the outermost point n4 of the exposed surface 260S of the second filler 260P may protrude further outwardly than the outermost points n1 and n2 of the first and second side surfaces Sa and Sb, but an example implementation thereof is not limited thereto.

Since the second filler 260P does not include impurities similarly to the first filler 250P, even when the second filler 260P includes the same insulating material as that of the first filler 250P of the first recess portion G1, the second filler 260P may have a second density different from the first. That is, the second density of the second filler 260P may have a greater value than the first density of the first filler 250P.

As described above, the first filler 250P may be cured, the second filler 260P may be injected, and the second filler 260P may be cured. However, as illustrated in FIGS. 1 and 6, the first and second fillers 250P and 260P may be cured simultaneously. The curing process may be performed in a range of about 200 degrees to 420 degrees. By the curing of the first and second fillers 250P and 260P, a buffer structure SS burying the first and second recess portions G1 and G2 of the side surfaces Sa and Sb of the bonded structure may be formed. The buffer structure SS may include the first buffer layer 250 in the first recess portion G1 and the second buffer layer 260 in the second recess portion G2.

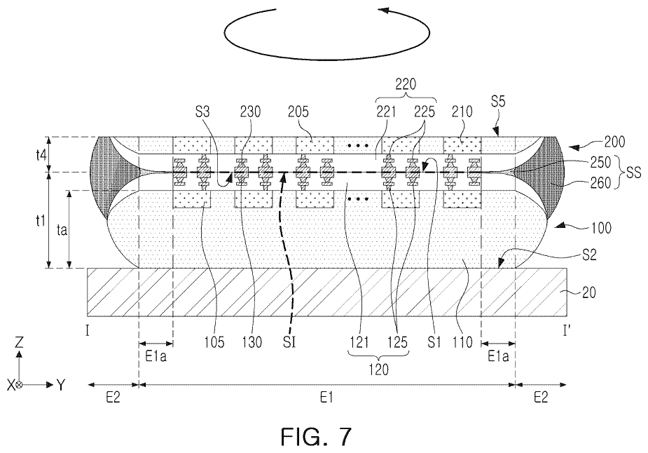

Referring to FIGS. 1 and 7, thinning may be performed from the back surface S4 of the second semiconductor wafer 200, which is the upper surface of the bonded structure, and the second thickness t2 may be changed to the fourth thickness t4 (S60).

The fourth thickness t4 of the second semiconductor wafer 200 may include the active region 205 in which the devices of the second semiconductor substrate 210 are disposed, and the second interconnection layer 220 may be included.

By thinning the second semiconductor wafer 200 to the fourth thickness t4, the lower surface of the active regions 205 may be exposed, and may be defined as the second back surface S5. The thinning process may include performing a mechanical grinding process, a chemical mechanical planarization (CMP) process, or any combination thereof. The thinning process may be performed while removing the upper end of the buffer structure SS together, and by the thinning process, the upper end of the second buffer layer 260 may be removed, and the cutout surface of the second buffer layer 260 may be coplanar with the second back surface S5. However, even in this thinning process, the first buffer layer 250 may not be exposed.

Since the buffer structure SS is disposed between the first and second semiconductor wafers 100 and 200, the risk of edge destruction due to the sharp and thin edge portion of the second semiconductor wafer 200 in the thinning process may be reduced, and a process such as edge trimming to compensate therefor may not be performed. Also, the risk of delamination due to the thin edge portion may be reduced, thereby improving reliability of the bonded structure.

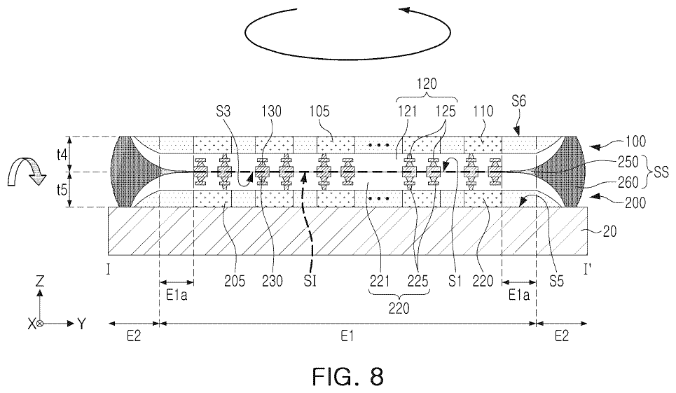

Referring to FIGS. 1 and 8, a thinning process of the first semiconductor wafer 100 may be performed (S70).

Specifically, the bonded structure may be disposed upside down such that the back surface S2 of the first semiconductor wafer 100 may be exposed upwardly, and thinning may be performed to have a third thickness t3 from the exposed back surface S2 of the first semiconductor wafer 100.

The third thickness t3 of the first semiconductor wafer 100 may include the active region 105 in which devices are disposed in the first semiconductor substrate 110, and may have a second back surface S6 exposing the lower surface of the active region 105. The third thickness t3 may be equal to or different from the fourth thickness t4.

That is, when the first chip region 102 and the second chip region 202 are the same, the third thickness t3 and the fourth thickness t4 may be the same, but when the first chip region 102 and the second chip region 202 are different, the third thickness t3 may be different from the fourth thickness t4.

The thinning process of the first semiconductor wafer 100 may also include performing a mechanical grinding process, a chemical mechanical planarization (CMP) process, or any combination thereof. The thinning process may cut an uppermost end of the buffer structure SS to be coplanar with the second back surface S6, but the first buffer layer 250 may not be exposed.

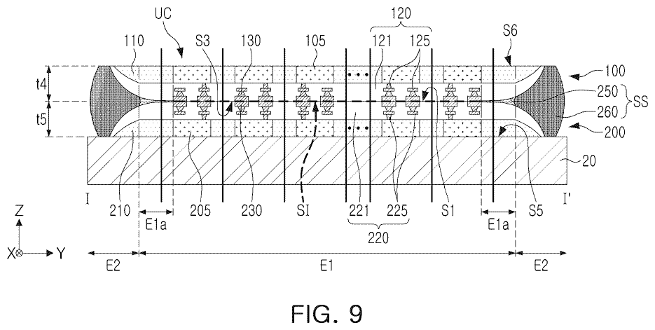

Referring to FIGS. 1 and 9, the bonded structure may be cut along the chip regions 102 and 202 and may be isolated as unit bonding chip structures UC (S80).

The cutting process may be performed by forming a laser groove along scribe lanes 104 and 204, and extending and separating both sides, and may be performed by sawing, or the like. The unit bonding chip structure UC may be provided in a state in which the first chip region 102 and the second chip region 202 are attached to each other by bonding between the first bonding pad 130 and the second bonding pad 230. The side surfaces of the first chip region 102 and the second chip region 202 may be aligned parallel in the Z direction, and may have a continuous surface without a bent portion.

In particular, in the cutting process, the second region E2 may be removed, and by cutting along the scribe lane in the edge region E1a, unit bonding chip structures UC including a portion of the first buffer layer 250 of the edge region E1a, for example, outermost unit bonding chip structures UC including the outermost first chip region 102 and the second chip region 202 in FIG. 4A may be formed.

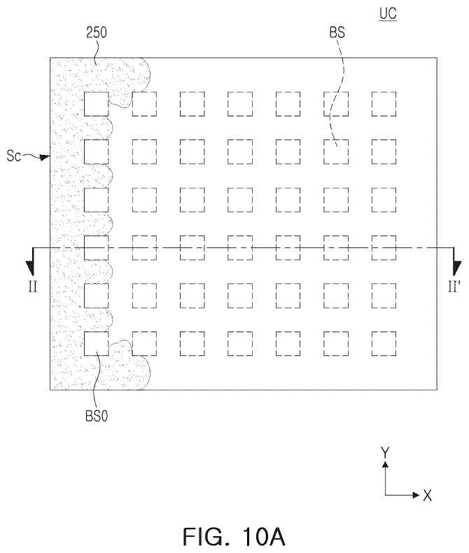

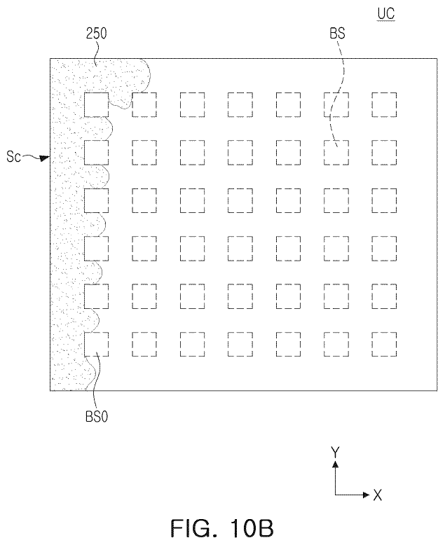

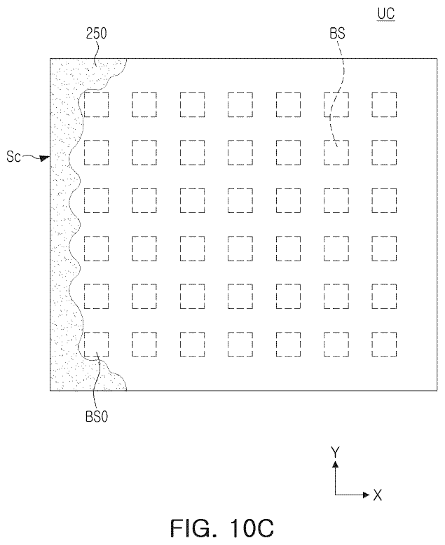

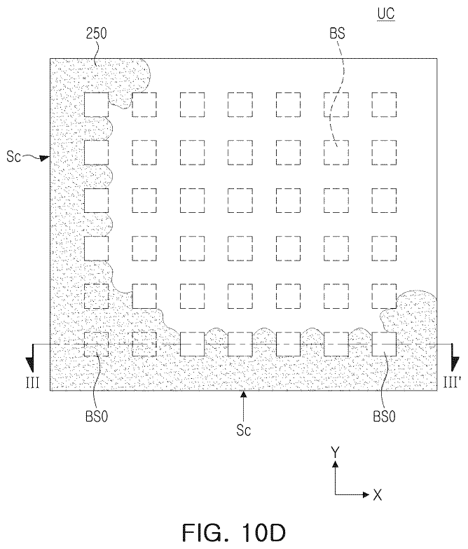

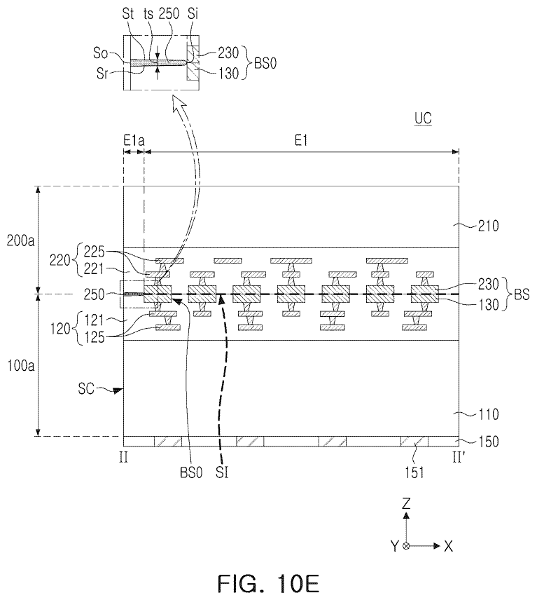

Hereinafter, a semiconductor device to which the unit bonding chip structure produced by FIGS. 1 to 9 according to an example implementation is applied will be described with reference to FIGS. 10A to 13.

FIGS. 10A, 10B, 10C, and 10D are diagrams viewed from above illustrating an example of a semiconductor device. FIG. 10E is a cross-sectional diagram illustrating the semiconductor device in FIG. 10A taken along line II-II′.

Referring to FIGS. 10A and 10B, the semiconductor device UC may be a unit bonding chip structure disposed in the outermost portion of the unit bonding chip structures manufactured by FIGS. 1 to 9. In the example implementation, the semiconductor device UC may have a quadrangular shape, for example, a rectangle or a square, when viewed from an upper surface, and the upper surface and the lower surface may have the same area, but according to an example implementation, the area may increase toward the lower surface. The semiconductor device UC may include at least four side surfaces between the upper surface and the lower surface, and at least one of the four side surfaces may include the reinforcing side surface Sc illustrated in FIG. 4A. The semiconductor device UC may include two chip structures 100a and 200a. The semiconductor chip structures 100a and 200a may have the same area, but an example implementation thereof is not limited thereto. The lower chip structure 100a and the upper chip structure 200a may have continuous side surfaces without a bent portion, and when the side surfaces have a slope, the angle of the slope may be constant.

The lower chip structure 100a may include a first semiconductor substrate 110, a first interconnection layer 120 on the first semiconductor substrate 110, first bonding pads 130 on the first interconnection layer 120, and lower pads 151 on the lower surface of the first semiconductor substrate 110.

The first semiconductor substrate 110 may include silicon. The first semiconductor substrate 110 may include various impurity regions for individual devices, a device isolation structure such as a shallow trench isolation (STI) structure, and a metal material forming a portion of the interconnection structure.

The first interconnection layer 120 may include an interconnection structure 125 connected to a plurality of individual devices formed on an active surface of a first semiconductor substrate 110. The interconnection structure 125 may include a metal interconnection layer and a metal via. For example, the multilayer interconnection structure 125 may be a multilayer structure including two or more metal interconnection layers and/or two or more vias. The interconnection structure 125 may be connected to first bonding pads 130 disposed on an upper surface of the first interconnection layer 120.

As for the first interconnection layer 120, a multilayer interconnection structure 125 may be disposed in the first insulating layer 121, and the first insulating layer 121 may be an oxide or a nitride, and may preferably be formed of silicon oxide (SiOx).

The first interconnection layer 120 may be disposed to occupy substantially the same area as the area of the semiconductor substrate 110. The side surfaces of the first semiconductor substrate 110 and the first interconnection layer 120 may be continuous without bending. The edge region E1a corresponding to the distance from the upper surface of the first interconnection layer 120 to the first bonding pad 130 positioned close to the outermost side surface may be defined as a dummy region.

The lower insulating layer 150 may be disposed as a lower passivation layer on the lower surface of the first semiconductor substrate 110.

The upper surface of the first interconnection layer 120, that is, the upper surface of the first insulating layer 121 and the first bonding pads 130 may be substantially coplanar with the upper surface of the lower chip structure 100a, and may be exposed. The upper portion of the first insulating layer 121 may function as a bonding insulating layer and may include a separate bonding insulating layer.

An upper chip structure 200a may be disposed on a lower chip structure 100a. The upper chip structure 200a may include a second semiconductor substrate 210, a second interconnection layer 220 in a lower portion of the second semiconductor substrate 210, and second bonding pads 230 in a lower portion of the second interconnection layer 220.

The second semiconductor substrate 210 may include silicon. The second semiconductor substrate 210 may include various impurity regions for individual devices, a device isolation structure such as a shallow trench isolation (STI) structure, and a metal material forming a portion of the interconnection structure. The second semiconductor substrate 210 may have substantially the same area as the first semiconductor substrate 110.

The second interconnection layer 220 may include an interconnection structure 225 connected to a plurality of individual devices formed on an active surface of a second semiconductor substrate 210. The interconnection structure 225 may include a metal interconnection layer and a metal via. For example, the multilayer interconnection structure 225 may be a multilayer structure including two or more metal interconnection layers and/or two or more vias. The interconnection structure 225 may be connected to second bonding pads 230 disposed on a lower surface of the second interconnection layer 220.

As for the second interconnection layer 220, the multilayer interconnection structure 225 may be disposed in a second insulating layer 221, and the second insulating layer 221 may be an oxide or a nitride, and may preferably be formed of silicon oxide (SiOx)

The second interconnection layer 220 may be disposed to occupy substantially the same area as the area of the second semiconductor substrate 210. The side surfaces of the second semiconductor substrate 210 and the second interconnection layer 220 may be continuous without a bend. The edge region E1a corresponding to the distance from the side surface to the second bonding pads 230 positioned at the outermost edge closest to the side surface may be defined as a dummy region on the lower surface of the second interconnection layer 220.

In FIG. 10B, the upper chip structure 200a may not include through-electrodes, but alternatively, the upper chip structure 200a may further include through-electrodes penetrating the second semiconductor substrate 210. As for the lower surface of the upper chip structure 200a, the lower surface of the second insulating layer 221 and the second bonding pads 230 may be substantially coplanar with the lower surface of the second interconnection layer 220 and may be exposed. The lower portion of the second insulating layer 221 may function as a bonding insulating layer.

The first bonding pads 130 and the second bonding pads 230 between the adjacent chip structures 100a and 200a may be directly bonded to each other, may form “intermetallic bonding” and may form bonding structures BS, respectively. This intermetallic bonding may mechanically fix the adjacent chip structures 100a and 200a to each other, and may provide a path for transmitting and receiving at least one of a control signal, a power signal, a ground signal, and a data signal. In particular, the intermetallic bonding between the first bonding pads 130 and the second bonding pads 230 may reduce transmission loss since the bonding may not use an additional conductive bump such as a solder.

The first bonding pads 130 and the second bonding pads 230 may include the same metal, for example, copper (Cu). The first bonding pads 130 and the second bonding pads 230 may be bonded to each other to be in direct contact with each other and may be firmly coupled to each other by mutual diffusion of copper through a high temperature annealing process. The metal forming the first bonding pads 130 and the second bonding pads 230 is not limited to copper, and may include other metal materials (e.g., gold) which may be mutually bonded.

In the example implementation, the bonding between adjacent chip structures 100a and 200a may form hybrid bonding including “interdielectric bonding” in addition to the metal bonding described above. As illustrated in FIG. 3B, the inter-dielectric bonding may be formed by directly bonding the first and second insulating layers 121 and 221 of the chip structures 100a and 200a to each other. The inter-dielectric bonding between the first and second insulating layers 121 and 221 may be implemented by covalent bonding. The bonding structure BS may have stronger bonding strength by inter-dielectric bonding. The insulating material forming the first and second insulating layers 121 and 221 is not limited to silicon oxide, and may include materials which may be coupled to each other (e.g., SiCN).

The lower chip structure 100a and the upper chip structure 200a may be integrated by bonding between the first bonding pad 130 and the second bonding pad 230, which are bonding structures BS, and may form a cut unit chip structure UC. The lower chip structure 100a and the upper chip structure 200a may extend continuously without bending while side surfaces thereof are aligned with each other in the Z-direction. The lower chip structure 100a and the upper chip structure 200a may have side surfaces disposed perpendicular to the upper surface, but may have a slope depending on the cutting method.

The bonding surface S1 of the lower chip structure 100a and the upper chip structure 200a may be defined by bonding between the upper surface of the first insulating layer 121 of the first interconnection layer 120 and the lower surface of the second insulating layer 221 of the second interconnection layer 220. Also, the bonding surface S1 of the lower chip structure 100a and the upper chip structure 200a may be defined as the bonding surface S1 of the first bonding pads 130 and the second bonding pads 230.

In the bonding surface of the semiconductor device UC, the bonding structures BS may be arranged in various manners depending on the shapes of the first bonding pads 130 and the second bonding pads 230.

For example, as illustrated in FIGS. 10A to 10D, the dot shapes having a predetermined spacing distance, spaced apart from each other and may be arranged in a matrix form may be formed. Each dot shape may be a quadrangular shape or a circular shape, but an example implementation thereof is not limited thereto. Among the first bonding pads 130 and the second bonding pads 230, the outermost first bonding pads 130 and the second bonding pads 230, which are closest to the side surface of the semiconductor device UC of the lower chip structure 100a and the upper chip structure 200a, may overlap each other in the Z-direction, may be in direct contact with each other and may form outermost bonding structures BSo. The outermost bonding structures BSo may be arranged in a frame shape with respect to the four side surfaces as illustrated in FIGS. 10A to 10D when viewed from the upper surface. The shapes of the outermost bonding structures BSo and the inner bonding structures BS may be substantially the same, but an example implementation thereof is not limited thereto. A portion of the bonding structures BS may be a dummy bonding structure not connected to the interconnection structures 125 and 225.

The semiconductor device UC may further include a buffer structure 250 between the edge region E1a of the lower chip structure 100a and the upper chip structure 200a.

As illustrated in FIG. 10A, the buffer structure 250 may extend from the reinforcing side surface Sc of the semiconductor device UC to the outermost bonding structure BSo in the XY-direction. The semiconductor device UC may include an edge region E1a between the outermost bonding structure BSo and the reinforcing side surface Sc, and the buffer structure 250 may be disposed in the edge region E1a. As illustrated in FIG. 10A, the buffer structure 250 may have a shape protruding further toward an inner side between the outermost bonding structures BSo than the outermost bonding structure BSo by diffusing a portion between the outermost bonding structures BSo spaced apart from each other. Also, the buffer structure 250 may protrude to a greater length at the corner of the adjacent side surfaces of the reinforcing side surface Sc.

As illustrated in FIG. 10B, when the direction in which the first filler is injected is disposed closer to one side of the reinforcing side surface Sc according to the disposed position in the wafer to which the semiconductor device UC is bonded, the length protruding between the outermost bonding structure BSo may not be uniform. That is, the diffusion may be performed with a greater length in a region close to the injection direction, and may have a smaller length in a region far from the injection direction.

In FIGS. 10A, 10B, and 10E, the buffer structure 250 may extend from the reinforcing side surface Sc of the semiconductor device UC to the outermost bonding structure BSo, but as illustrated in FIG. 10C, the buffer structure 250 may be disposed by diffusing only to a predetermined distance from the reinforcing side surface Sc without being in contact with the outermost bonding structure BSo, and may have a space having a predetermined size in a region with the outermost bonding structure BSo.

The buffer structure 250 may be an insulating material having a first density and may include polysilicon, silicon oxide, or silicon nitride. The upper surface St may be in contact with the second insulating layer 221 of the upper chip structure 200a, and the lower surface Sr may be in contact with the first insulating layer 121 of the lower chip structure 100a. An external side surface So and an internal side surface S1 may be disposed between the upper surface St and the lower surface Sr. The external side surface So may be coplanar with the reinforcing side surface Sc of the semiconductor device UC, and an inner side surface S1 may be in contact with the outermost bonding structure BSo, or may have a space and may face the outermost bonding structure BSo as in FIG. 10C.

When the lower chip structure 100a is bonded to the upper chip structure 200a, the buffer structure 250 may be a portion a of the first buffer layer 250 buried in the first recess portion G1 extending from between the first side surface Sa and the second side surface Sb of the wafer unit when the region in which the insulating layers 121 and 221 face each other on the external side of the outermost bonding structure BSo corresponds to the edge region E1a of the wafer unit.

Accordingly, in the buffer structure 250, a distance ts between the upper surface St and the lower surface Sr may decrease from the external side surface So to an inner side surface S1, and may converge to a line at an inner side surface S1, but an example implementation thereof is not limited thereto. The buffer structure 250 may be disposed in various forms depending on the region in which the semiconductor device UC is positioned in the wafer unit.

The lower chip structure 100a may include a memory circuit, a processor circuit, or the like, and the upper chip structure 200a may include circuits different from the lower chip structure 100a. For example, the upper chip structure 200a may include peripheral circuits for driving the circuits of the lower chip structure 100a, such as an input/output circuit, an analog circuit, a serial-parallel conversion circuit, or the like.

The lower chip structure 100a may include memory devices such as flash memory, memory device such as dynamic random access memory (DRAM), Static random access memory (SRAM), electrically erasable programmable read-only memory (EEPROM), Phase-change random access memory (PRAM), magnetoresistive random access memory (MRAM), ferroelectric random access memory (FeRAM), resistive random access memory (RRAM), and the upper chip structure 200a may be a peripheral circuit for driving the lower semiconductor chip, and may include various active and/or passive components, such as FETs such as planar Field Effect Transistor (FET) or FinFETs, logic devices such as ANDs, ORs, and NOTs, system large scale integration (LSI), CMOS imaging sensor (CIS), and micro-electro-mechanical systems (MEMS).

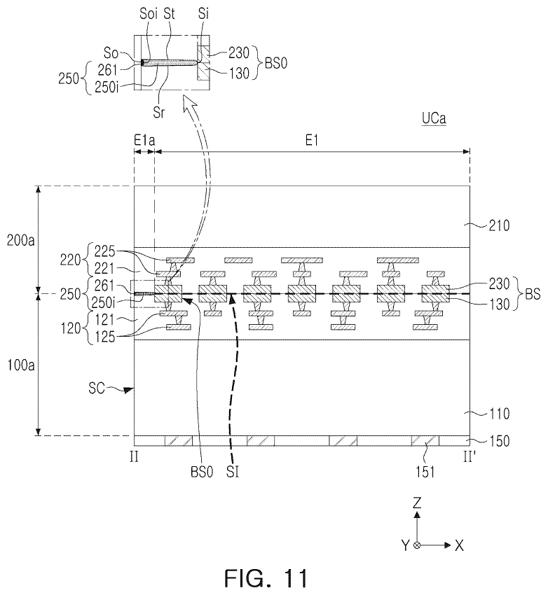

Referring to FIG. 11, the semiconductor device UCa may be the same as the semiconductor device UC in FIG. 10E other than the buffer structure 250.

The semiconductor device UCa may include a buffer structure 250 between the edge region E1a of the upper chip structure 200a and the lower chip structure 100a in at least one reinforcing side surface Sc.

The buffer structure 250 may include a first buffer layer 250i and a second buffer layer 261.

The upper surface St of the first buffer layer 250i may be in contact with the second insulating layer 221 of the upper chip structure 200a, and the lower surface Sr may be in contact with the first insulating layer 121 of the lower chip structure 100a. The external side surface Soi and the inner side surface S1 between the upper surface St and the lower surface Sr may be disposed, and the external side surface Soi may be in contact with the second buffer layer 261, and an inner side surface S1 may be in contact with the outermost bonding structure BSo or may have a space and may face the outermost bonding structure BSo. The first buffer layer 250i may be disposed to be recessed from the reinforcing side surface Sc of the semiconductor device UCa, and the external side surface Soi of the first buffer layer 250i may be disposed on the inner side than the reinforcing side surface Sc of the semiconductor device UCa.

An inner side surface S1 of the first buffer layer 250i may be formed to have an inwardly curved surface toward the center of the semiconductor device UCa, but an example implementation thereof is not limited thereto. The first buffer layer 250i may be an insulating material having a first density, and may include polysilicon, silicon oxide, or silicon nitride.

The second buffer layer 261 may be disposed on the external side surface Soi of the first buffer layer 250i.

The second buffer layer 261 may be disposed to be bent such that the internal side surface Soi may be in contact with the external side surface So at the upper and lower ends, and the upper and lower ends may be spaced apart from each other, and an inner side surface Soi may be in contact with the external side surface Soi of the first buffer layer 250i, and the external side surface So may be coplanar with the reinforcing side surface Sc of the semiconductor device UC, and may extend flatly without a curved surface.

The second buffer layer 261 may be a material having different properties from that of the first buffer layer 250i, and for example, may include an insulating material having a second density higher than the first density. The second buffer layer 261 may include polysilicon, silicon oxide, or silicon nitride, but even when the second buffer layer 261 includes the same material as that of the first buffer layer 250i, the density may be different such that the boundary surface may be clearly distinct.

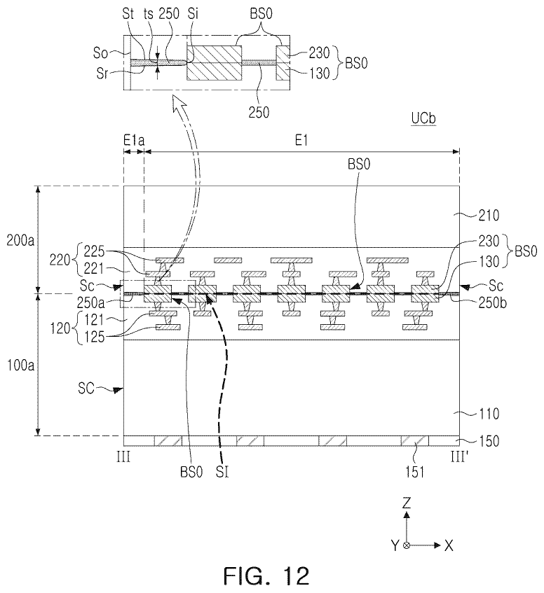

Referring to FIGS. 10D and 12, the semiconductor device UCb may be the same as the semiconductor device UC in FIG. 10E other than the buffer structures 250a and 250b. FIG. 12 is a cross-sectional diagram illustrating the semiconductor device UCb in FIG. 10D taken along line III-III′.

The semiconductor device UCb in FIG. 10D and FIG. 12 may further include buffer structures 250a and 250b between edge regions E1a of the upper chip structure 200a and the lower chip structure 100a on at least two reinforcing side surfaces Sc, for example, two side surfaces folded continuously. In this case, the buffer structures 250a and 250b may be the buffer structure 250 in FIG. 10E, but may also be the buffer structure 250 including two buffer layers 250i and 261 as in FIG. 11.

When the buffer structures 250a and 250b are disposed on at least two reinforcing side surfaces Sc of the semiconductor device UC, the semiconductor device UC may be disposed in a position in the wafer unit in which two or more side surfaces are in contact with the edge region E1a. At least two reinforcing side surfaces Sc, on which buffer structures 250a and 250b are disposed, may be adjacent side surfaces, and buffer structures 250a and 250b may be disposed toward outermost bonding structures BSo adjacent to at least two reinforcing side surfaces Sc, as illustrated in FIG. 12. The buffer structures 250a and 250b may include regions in which the filler diffuses through a region between the outermost bonding structures BSo in vicinity of the corner to the internal side of the outermost bonding structures BSo by injecting a larger amount of first filler at the corner at which the two reinforcing side surfaces meet. Accordingly, in FIG. 12, the outermost bonding structures BSo disposed at the corner may be surrounded by the buffer structures 250a and 250b, but an example implementation thereof is not limited thereto.

Referring to FIG. 12, when cutting along the outermost bonding structures BSo, at least a portion of buffer structures 250a and 250b may be dispersed and disposed between the outermost bonding structures BSo.

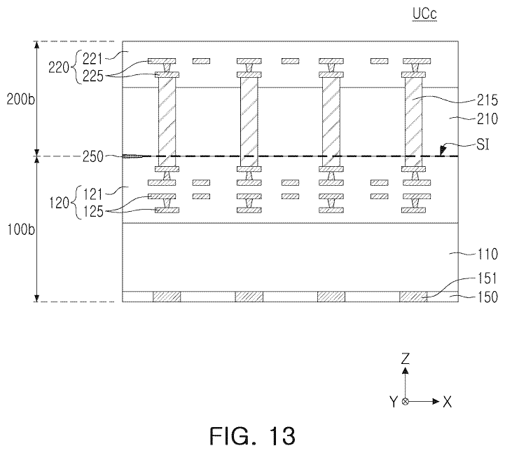

Referring to FIG. 13, the semiconductor device UCc may be the same as the semiconductor device UC in FIG. 10B other than the upper chip structure 200b.

The semiconductor device UCc may be formed directly without bonding the lower chip structure 100a and the upper chip structure 200b.

That is, rather than forming a first semiconductor wafer 100 including the lower chip structure 100a as the first chip regions 102 and forming a second semiconductor wafer 200 including the upper chip structure 200b as the second chip regions 202, a second semiconductor substrate 210 may be formed on the first semiconductor wafer 100, and the second chip regions 202 may be formed after thinning the second semiconductor substrate 210.

Accordingly, rather than the structure in which the upper and lower chip structures 100a, 200b are formed individually and bonded, a structure in which the upper chip structure 200b is formed on the lower chip structure 100a may be formed.

Since the second semiconductor substrate 210 is directly formed on the lower chip structure 100a, bonding between the two chip regions 100a, 200b may be performed without a separate bonding structure BS.

Similarly, by directly forming the lower chip structure 100a and the upper chip structure 200b, the first filler 250P and the second filler 260P may be formed on the edge region E1a of the wafer, and may be cut out, thereby forming the buffer structure 250.

Accordingly, the second semiconductor substrate 210 may be disposed directly on the first interconnection layer 120 of the lower chip structure 100a, and the second interconnection layer 220 may be disposed on the second semiconductor substrate 210.

Through-electrodes 215 penetrating the second semiconductor substrate 210 to connect the interconnection structures 225 of the second interconnection layer 220 to the interconnection structures 125 of the first interconnection layer 120 may be further disposed, but an example implementation thereof is not limited thereto.

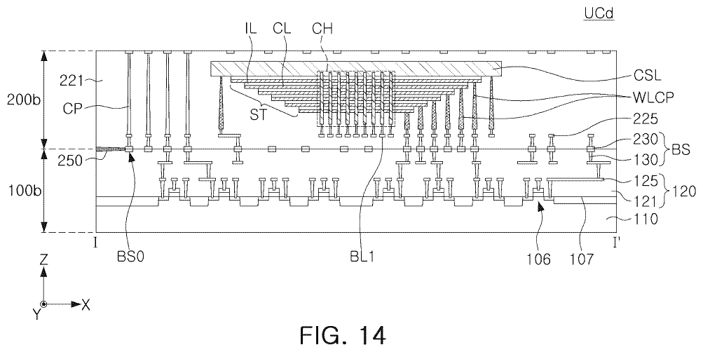

Referring to FIG. 14, the semiconductor device UCd may be the same as the semiconductor device UC in FIG. 10E, other than the configuration in which a vertical memory structure is applied to the upper chip structure 200a, and a peripheral circuit structure driving the same is applied to the lower chip structure 100a.

The upper chip structure 200a and the lower chip structure 100a of the semiconductor device UCd in FIG. 14 may be bonded to each other through bonding structures BS, 130, and 230.

The lower chip structure 100a may include a first semiconductor substrate 110, circuit devices 106 on the first semiconductor substrate 110, a lower interconnection layer 120, and lower bonding pads 130.

The circuit devices 106 may include transistors in an active region isolated by the device isolation regions 107. Each circuit device 106 may include a circuit gate dielectric layer, a circuit gate electrode, a spacer layer, and a source/drain region. Source/drain regions including impurities may be disposed in the first semiconductor substrate 110 on both sides of the circuit gate electrode. The spacer layers may be disposed on both sides of the circuit gate electrode. The circuit gate dielectric layer may include silicon oxide, silicon nitride, or a high-material.

A lower interconnection insulating layer 121 covering each circuit device 106 may be disposed, and lower interconnections 125 may be disposed in the lower interconnection insulating layer 121 and may form the lower interconnection layer 120. Lower bonding pads 130 may be exposed on an upper surface of the lower interconnection insulating layer 121.

The upper chip structure 200a may include a plurality of channel structures CH, which are memory cell structures. The upper chip structure 200a may include a stack structure St in which gate electrodes CL and interlayer insulating layers (IL) are intersected and stacked, channel structures CH disposed by vertically penetrating the stack structure St, and a common source structure CSL which may be electrically connected to one end of the channel structures CH may be disposed on the stack structure St.

The stack structure St may have wordline contact plugs WLCP disposed electrically connected to each of the gate electrodes CL on at least one side, and through-vias CP connected to an external entity may be disposed at the edge region.

The upper interconnections 225 connected to the through-vias CP, the channel structures CH, and the wordline contact plugs WLCP may be disposed, and the upper interconnections 225 and upper bonding pads 230 may be connected to each other.

The upper interconnections 225 may include bitlines BL connected to the channel structures CH.

The upper chip structure 200a including the channel structures CH, which are memory cell structures, may be physically and electrically connected to the lower chip structure 100a by the bonding structure BS and may form a single unit chip structure UCd.

As illustrated in FIG. 14, in the case in which the unit chip structure UCd is a NAND structure, bonding may be performed upside down for bonding with the lower chip structure 100a, which is a peripheral circuit structure, the second semiconductor substrate 210 of the upper chip structure 200a may be completely removed, and only the active regions 205 of the second chip region 202, that is, the device region, may be disposed.

The unit chip structure UCd in FIG. 14 may include a buffer structure 250 in which the bonding structure BS is disposed from the reinforcing side surface Sc toward the bonding surface.

The buffer structure 250 may be disposed as a reinforcing side surface Sc as illustrated in FIG. 14, but an example implementation thereof is not limited thereto, and may extend from a plurality of side surfaces including the reinforcing side surface Sc. The buffer structure 250 in FIG. 14 may also be defined as a structure diffusing toward the outermost bonding structures BSo in vicinity of the corner by first filler injection from the wafer unit to the side surface, and may include an insulating material of polysilicon, silicon oxide, or silicon nitride having a first density.

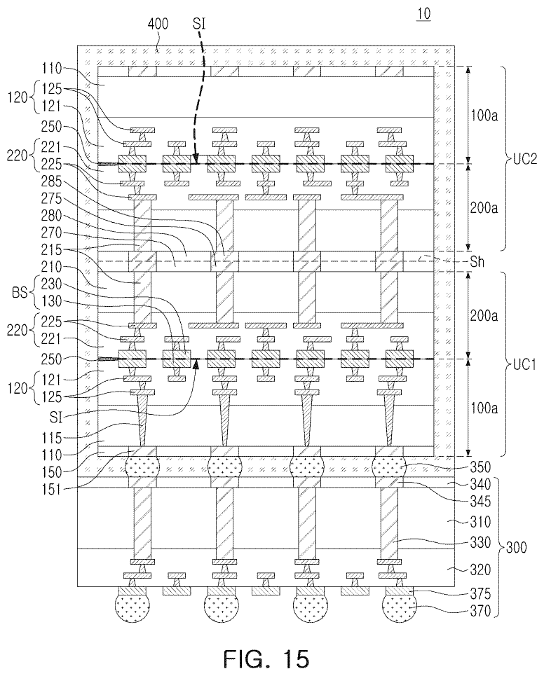

Referring to FIG. 15, the semiconductor package 10 may form a multilayer structure by attaching a plurality of first and second semiconductor devices UC1 and UC2 in FIG. 10 to the base structure 300.

The base structure 300 may include lower connection pads 352 disposed on the lower surface and upper connection pads 345 disposed on the upper surface. In the example implementation, the base structure 300 may have a width (that is, area) greater than the width of the semiconductor device UC.

The lower chip region 100a in the first semiconductor device UC1 may be connected to upper connection pads 345 through solder bumps 350 on the base structure 300.

An upper insulating layer 340 may be formed on an upper surface of the base structure 300 employed in the example implementation, and the upper insulating layer 340 may have an upper surface substantially coplanar with the upper connection pads 345.

A connection bump 370 may be attached to the lower portion connection pads 375 of the base structure 300. The connection bump 370 may be, for example, a solder ball or a conductive bump. The connection bump 370 may electrically connect the base structure 300 to a printed circuit substrate, such as a motherboard. The base structure 300 may be a buffer chip, and may include a semiconductor substrate 310, an interconnection layer 320, and a through-via 330, similar to the semiconductor devices UC1 and UC2. For example, the interconnection layer 320 may include a logic device.

In the semiconductor package 10 in FIG. 15, a first semiconductor device UC1 may be disposed on the base structure 300, and a second semiconductor device UC2 may be stacked on the first semiconductor device UC1. The first semiconductor device UC1 and the second semiconductor device UC2 may be the same as the semiconductor device UC in FIG. 10E.

In the first semiconductor device UC1 and the second semiconductor device UC2, the first bonding insulating layer 270 and upper bonding pads 275 may be further disposed on the upper surface of the second semiconductor substrate 210 of the upper chip structure 200a of the first semiconductor device UC1, and the second bonding insulating layer 280 and lower bonding pads 285 may be further disposed on the lower surface of the upper chip structure 200a of the second semiconductor device UC2. Also, the through-electrodes 215 connected to the upper bonding pads 275 and the lower bonding pads 285, respectively, may further be disposed.

The first bonding insulating layer 270 and the second bonding insulating layer 280 of the first semiconductor device UC1 and the second semiconductor device UC2 may form organic bonding, and the upper bonding pads 275 and the lower bonding pads 285 may form intermetallic bonding, such that electrical and physical bonding between the two semiconductor devices UC1 and UC2 may be formed, thereby forming a bonding surface Sh between the chips.

In this case, the side surfaces of the first semiconductor device UC1 and the second semiconductor device UC2 may extend continuously without a bent portion, but an example implementation thereof is not limited thereto. The side surfaces may be perpendicular to or sloped with respect to the upper surface of the base structure 300.

A bonding surface S1 may be formed between the upper chip structure 200a and the lower chip structure 100a of the first semiconductor device UC1, and a portion of the bonding surface S1, that is, a buffer structure 250 may be disposed between the edge region E1a. The bonding surface S1 may be formed between the upper chip structure 200a and the lower chip structure 100a of the second semiconductor device UC2, and a portion of the bonding surface S1, that is, a buffer structure 250 may be disposed between the edge region E1a. The buffer structure 250 may not be disposed in the inter-chip bonding surface Sh between the first semiconductor device UC1 and the second semiconductor device UC2.

While forming the inter-chip bonding surface Sh as described above, the plurality of semiconductor devices UC1 and UC2 may include the same circuits. For example, a semiconductor chip having a volatile memory device may be provided.

The encapsulant 400 may cover an upper surface of the plurality of semiconductor devices UC1 and UC2 and the base structure 300. The encapsulant 400 may cover a side surface of the plurality of semiconductor devices UC1 and UC2. The encapsulant 400 may include, for example, a thermosetting resin such as an epoxy resin, a thermoplastic resin such as a polyimide, or a prepreg, ABF, FR-4, BT, epoxy molding compound (EMC). For example, the encapsulant 400 may include EMC.

According to the aforementioned example implementations, by injecting a filler into the side recess portion between the bonded wafer structures after bonding semiconductor wafers to each other, a material having different viscosities depending on the shape of the recess portion may be provided. Accordingly, by burying even the fine recess portion between the wafer structures, crack propagation by the thin side surface of the recess portion during the subsequent thinning process of the semiconductor wafer may be prevented. Accordingly, the semiconductor chip region disposed in the edge region of the semiconductor wafer may be used as an effective semiconductor chip region rather than a dummy chip region, such that yield and reliability may be assured.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the example implementations have been illustrated and described above, it will be configured as apparent to those skilled in the art that modifications and variations could be made without departing from the scope of the present disclosure as defined by the appended claims.

What is claimed is:

1. A semiconductor chip, comprising:
a first semiconductor structure including a first semiconductor substrate and a first interconnection layer, the first interconnection layer being disposed on the first semiconductor substrate and including a first plurality of interconnection structures and a first plurality of bonding pads, the first plurality of bonding pads being connected to the first plurality of interconnection structures and exposed on an upper surface of the first interconnection layer;
a second semiconductor structure including a second semiconductor substrate and a second interconnection layer, the second semiconductor substrate being disposed on the first semiconductor structure, the second interconnection layer being disposed on the second semiconductor substrate and including a second plurality of interconnection structures and a second plurality of bonding pads, the second plurality of bonding pads being connected to the second plurality of interconnection structures and exposed on a lower surface of the second interconnection layer; and
a buffer structure extending from at least one side surface of the first semiconductor structure and the second semiconductor structure to a bonding surface between the first interconnection layer and the second interconnection layer.

2. The semiconductor chip of claim 1,
wherein a first side surface of the first semiconductor structure and a second side surface of the second semiconductor structure are aligned in a vertical direction, and
wherein the first side surface of the first semiconductor structure, the second side surface of the second semiconductor structure, and an external side surface of the buffer structure are coplanar with each other.

3. The semiconductor chip of claim 1, wherein the buffer structure includes an insulating material.

4. The semiconductor chip of claim 1, wherein the first plurality of bonding pads and the second plurality of bonding pads are bonded to each other and form a plurality of bonding structures, and the buffer structure extends from the at least one side surface of the first semiconductor structure and the second semiconductor structure toward an outermost bonding structure among the plurality of bonding structures.

5. The semiconductor chip of claim 4, wherein an upper surface of the buffer structure contacts an upper surface of the first semiconductor structure, a lower surface of the buffer structure contacts a lower surface of the second semiconductor structure, and an internal side surface between the upper surface and the lower surface of the buffer structure contacts the outermost bonding structure.

6. The semiconductor chip of claim 1, wherein the buffer structure includes:
a first buffer layer having an external side surface extending from an internal side surface and disposed on an inner side of the at least one side surface of the first semiconductor structure and the second semiconductor structure; and
a second buffer layer having an internal side surface contacts the external side surface of the first buffer layer and an external side surface coplanar with the at least one side surface of the first semiconductor structure and the second semiconductor structure.

7. The semiconductor chip of claim 6, wherein the first buffer layer has a first density, and the second buffer layer has a second density greater than the first density.

8. The semiconductor chip of claim 6, wherein the first buffer layer and the second buffer layer include a same insulating material, the insulating material in the first buffer layer has a first density, and the insulating material in the second buffer layer has a second density different than the first density.

9. The semiconductor chip of claim 6, wherein a width of the first buffer layer is greater than a width of the second buffer layer.

10. The semiconductor chip of claim 4, wherein an inner side surface of the buffer structure defines a space of the outermost bonding structure.

11. The semiconductor chip of claim 4,
wherein the outermost bonding structure includes a plurality of bonding structures spaced apart from each other, and
wherein the buffer structure includes a region extending into a spacing between the plurality of bonding structures.

12. The semiconductor chip of claim 1,
wherein the first interconnection layer includes a first insulating layer exposing the first plurality of bonding pads on an upper portion of the first interconnection layer, and the second interconnection layer includes a second insulating layer exposing the second plurality of bonding pads on a lower portion of the second interconnection layer, and
wherein the first insulating layer and the second insulating layer are bonded to each other.

13. The semiconductor chip of claim 1, wherein the buffer structure extends from at least two side surfaces of the semiconductor chip.

14. The semiconductor chip of claim 1,
wherein the first semiconductor structure includes a plurality of memory cells, and
wherein the second semiconductor structure includes a plurality of peripheral circuit devices driving the plurality of memory cells.

15. A semiconductor chip, comprising:
a first semiconductor structure including a first semiconductor substrate and a first interconnection layer, the first interconnection layer being disposed on the first semiconductor substrate and including a first interconnection structure;
a second semiconductor structure including a second semiconductor substrate and a second interconnection layer, the second semiconductor substrate being disposed on the first semiconductor structure, the second interconnection layer being disposed on a lower portion of the second semiconductor substrate and including a second interconnection structure;
a plurality of bonding structures in which a first plurality of bonding pads and a second plurality of bonding pads are bonded to each other vertically, the first plurality of bonding pads being connected to the first interconnection structure and having a plurality of upper surfaces exposed from the first interconnection layer, the second plurality of bonding pads being connected to the second interconnection structure and having a plurality of lower surfaces exposed from the second interconnection layer; and
a buffer structure provided at a side recess portion recessed from an outer side toward an outermost bonding structure among the plurality of bonding structures between an upper surface of the first interconnection layer and a lower surface of the second interconnection layer.

16. The semiconductor chip of claim 15, wherein the side recess portion includes a slit shape between the upper surface of the first interconnection layer and the lower surface of the second interconnection layer.

17. The semiconductor chip of claim 15, wherein the buffer structure includes:
a first buffer layer having an internal side surface contacting the outermost bonding structure and an external side surface, the external side surface extending from an inner side surface and disposed on an inner side of the first semiconductor structure and the second semiconductor structure; and
a second buffer layer having an internal side surface contacting an external side surface of the first buffer layer and an external side surface coplanar with a side surface of the first semiconductor structure.

18. The semiconductor chip of claim 17, wherein the first buffer layer and the second buffer layer include a same insulating material, the first buffer layer has a first density, and the second buffer layer has a second density greater than the first density.

19. A semiconductor package, comprising:
a base structure including a plurality of lower connection pads disposed on a lower surface of the base structure and a plurality of upper connection pads disposed on an upper surface of the base structure, the plurality of upper connection pads being electrically connected to the plurality of lower connection pads;
at least one bonding chip structure disposed on the base structure, the at least one bonding chip structure including two semiconductor chip structures bonded to each other and a plurality of connection pads on a lower surface of the at least one bonding chip structure; and
a plurality of solder bumps attaching the plurality of upper connection pads to the plurality of connection pads,
wherein the at least one bonding chip structure includes:
a first semiconductor structure including a first semiconductor substrate and a first interconnection layer, the first interconnection layer being disposed on the first semiconductor substrate and including a first plurality of interconnection structures and a first plurality of bonding pads, the first plurality of bonding pads being connected to the first plurality of interconnection structures and exposed on an upper surface of the base structure;
a second semiconductor structure including a second semiconductor substrate and a second interconnection layer, the second semiconductor substrate being disposed on the first semiconductor structure, the second interconnection layer being disposed on a lower portion of the second semiconductor substrate and including a second plurality of interconnection structures and a second plurality of bonding pads, the second plurality of bonding pads being connected to the second plurality of interconnection structures and exposed on a lower surface of the base structure; and
a buffer structure extending from at least one side surface of the first semiconductor structure and the second semiconductor structure to a bonding surface between the first interconnection layer and the second interconnection layer.

20. The semiconductor package of claim 19, comprising:
a sealant surrounding at least one bonding chip structure on the base structure.
